(19) United States
(12) Patent Application Publication
(10) Pub. No.: US 2026/0105960 A1
(43) Pub. Date: Apr. 16, 2026

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Zhengliang Xia, Wuhan (CN); Yanwei Shi, Wuhan (CN); Quan Zhang, Wuhan (CN); Jing Li, Wuhan (CN)

(21) Appl. No.: 18/915,948

(22) Filed: Oct. 15, 2024

(30) Foreign Application Priority Data
Oct. 11, 2024 (CN) 202411419203.4

(51) Int. Cl. G11C 16/04; G11C 11/4074; G11C 16/30; H01L 29/06; H01L 29/423; H01L 29/66; H01L 29/775; H01L 29/786; H10B 12/00; H10B 41/20; H10B 41/35; H10B 41/41; H10B 43/20; H10B 43/35; H10B 43/40

(52) U.S. Cl. CPC G11C 16/0483; G11C 11/4074; G11C 16/30; H10B 12/09; H10B 12/50; H10B 41/20; H10B 41/35; H10B 41/41; H10B 43/20; H10B 43/35; H10B 43/40; H10D 30/014; H10D 30/43; H10D 30/6735; H10D 30/6757; H10D 62/121

(57) ABSTRACT

Three-dimensional (3D) memory devices and fabricating methods thereof are disclosed. In certain aspects, a memory device comprises: a first semiconductor structure comprising an array of memory cells; a second semiconductor structure including peripheral circuits on the first semiconductor structure, comprising: a semiconductor layer, first transistors at a first side of the semiconductor layer close to the first semiconductor structure, gate all around transistors in the semiconductor layer, first contact structures on the first side of the semiconductor layer and in contact with the first transistors and the gate all around transistors, and second contact structures on a second side of the semiconductor layer distant from the first semiconductor structure, and in contact with the gate all around transistors; and a pad-out structure comprising conductive pads coupled with the second contact structures.

### CROSS-REFERENCE TO RELATED APPLICATIONS

This application claims the benefit of priority to Chinese Application No. 202411419203.4, filed on Oct. 11, 2024, which is incorporated herein by reference in its entirety.

### TECHNICAL FIELD

The present disclosure generally relates to the field of semiconductor technology, and more particularly, to three-dimensional (3D) memory devices and fabricating methods thereof.

### BACKGROUND

With continuous rising and development of artificial intelligence (AI), big data, Internet of Things, mobile devices and communications, and cloud storage, etc., the demand for memory capacity are growing in an exponential way.

Planar memory devices are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral devices for controlling signals to and from the memory array.

### SUMMARY

One aspect of the present disclosure provides a memory device, comprising: a first semiconductor structure comprising an array of memory cells; a second semiconductor structure including peripheral circuits on the first semiconductor structure, comprising: a semiconductor layer, first transistors at a first side of the semiconductor layer close to the first semiconductor structure, gate all around transistors in the semiconductor layer, first contact structures on the first side of the semiconductor layer and in contact with the first transistors and the gate all around transistors, and second contact structures on a second side of the semiconductor layer distant from the first semiconductor structure, and in contact with the gate all around transistors; and a pad-out structure comprising conductive pads coupled with the second contact structures.

In some implementations, the first semiconductor structure further comprises a first interconnect layer comprising first interconnect structures coupled with the array of memory cells; and the second semiconductor structure further comprises a second interconnect layer comprising second interconnect structures coupled with the first contact structures.

In some implementations, the first semiconductor structure is hybrid bonded with the second semiconductor structure in a vertical direction, and the first interconnect structures are coupled with the second interconnect structures.

In some implementations, the second semiconductor structure further comprises: isolation structures extending through the semiconductor layer and between the transistors and/or the gate all around transistors.

In some implementations, the semiconductor layer is a monocrystal silicon layer having a thickness of less than 200 nm.

In some implementations, the pad-out structure further comprises a third interconnect layer comprising third interconnect structures coupled between the conductive pads and the second contact structures.

In some implementations, one first transistor comprises: a first gate on the first side of the semiconductor layer and in contact with one first contact structure; and a second gate on the second side of the semiconductor layer and in contact with one second contact structure.

In some implementations, one of the first contact structures is in contact with a gate of a first gate all around transistor; and one of the second contact structures is in contact with a gate of a second gate all around transistor.

In some implementations, one of the first contact structures is in contact with a first source/drain terminal of one gate all around transistor; and one of the second contact structures is in contact with a second source/drain terminal of the one gate all around transistor.

In some implementations, the one of the first contact structures or the one of the second contact structures is coupled with a through interconnect structure extending through the semiconductor layer.

In some implementations, the first semiconductor structure is a 3D NAND array comprising an array of vertical NAND memory strings.

In some implementations, the first semiconductor structure is a DRAM cells array comprising an array of vertical transistors and vertical capacitors.

In some implementations, each gate all around transistor comprises: a channel in the semiconductor layer; a first source/drain at the first side of the semiconductor layer; a second source/drain at the second side of the semiconductor layer; a gate dielectric layer laterally surrounding the channel, the first source/drain, and the second source/drain; and a gate structure embedded in the gate dielectric layer and laterally surrounding the channel.

In some implementations, a lateral dimension of a first end of each first contact structure close to the semiconductor layer is less than a lateral dimension of a second end of the first contact structure distant from the semiconductor layer; and a lateral dimension of a first end of each second contact structure close to the semiconductor layer is less than a lateral dimension of a second end of the second contact structure distant from the semiconductor layer.

Another aspect of the present disclosure provides a method of forming a memory device, comprising: forming a first semiconductor structure comprising an array of memory cells; forming a second semiconductor structure including peripheral circuits on the first semiconductor structure, comprising: forming first transistors at a first side of a semiconductor layer, forming gate all around transistors in the semiconductor layer, forming first contact structures on the first side of the semiconductor layer and in contact with the gate all around transistors, and forming second contact structures on a second side of the semiconductor layer distant from the first semiconductor structure, and in contact with the first transistors and the gate all around transistors; and bonding the first semiconductor structure and the second semiconductor structure.

In some implementations, forming the first semiconductor structure further comprises forming a first interconnect layer comprising first interconnect structures coupled with the array of memory cells; and forming the second semiconductor structure further comprises forming a second interconnect layer comprising second interconnect structures coupled with the first contact structures.

In some implementations, bonding the first semiconductor structure and the second semiconductor structure comprises: hybrid bonding the first semiconductor structure with the second semiconductor structure in a vertical direction, such that the first interconnect structures are coupled with the second interconnect structures.

In some implementations, forming the second semiconductor structure further comprises: forming isolation structures extending in the semiconductor layer and between the transistors and/or the gate all around transistors.

In some implementations, forming the second semiconductor structure further comprises: after forming the first transistors and the gate all around transistors, thinning the semiconductor layer from the second side, such that a thickness of the semiconductor layer is less than 200 nm.

In some implementations, forming each gate all around transistor comprises: forming a channel in the semiconductor layer; forming a first source/drain at the first side of the semiconductor layer; forming a gate dielectric layer laterally surrounding the channel; forming a gate structure embedded in the gate dielectric layer and laterally surrounding the channel; and after thinning the semiconductor layer, forming a second source/drain at the second side of the semiconductor layer;

In some implementations, thinning the semiconductor layer comprises: removing a portion of the semiconductor layer from the second side to expose the isolation structures and the gate dielectric layer.

In some implementations, the method further comprises: forming a pad-out structure comprising: forming a third interconnect layer comprising third interconnect structures in contact with the second contact structures; and forming conductive pads in contact with the third interconnect structures.

In some implementations, forming one first transistor comprises: forming a first gate on the first side of the semiconductor layer; and after thinning the semiconductor layer, forming a second gate on the second side of the semiconductor layer; wherein one first contact structure is formed to be in contact with the first gate, and one second contact structure is formed to be in contact with the second gate.

In some implementations, one of the first contact structures is formed to be in contact with a gate of a first gate all around transistor; and one of the second contact structures is formed to be in contact with a gate of a second gate all around transistor.

In some implementations, one of the first contact structures is formed to be in contact with a first source/drain terminal of one gate all around transistor; and one of the second contact structures is formed to be in contact with a second source/drain terminal of the one gate all around transistor.

In some implementations, forming the second semiconductor structure further comprises: forming a through interconnect structure extending through the semiconductor layer and coupled with the one of the first contact structures or the one of the second contact structures.

In some implementations, forming the first semiconductor structure comprises: forming a 3D NAND array comprising an array of vertical NAND memory strings.

In some implementations, forming the first semiconductor structure comprises: forming a DRAM cells array comprising an array of vertical transistors and vertical capacitors.

Another aspect of the present disclosure provides a memory device, comprising: a first semiconductor structure comprising an array of memory cells; and a second semiconductor structure including peripheral circuits on the first semiconductor structure, and comprising: a semiconductor layer, a memory control circuit comprising first transistors at a first side of the semiconductor layer close to the first semiconductor structure, a power supply circuit comprising gate all around transistors in the semiconductor layer, first contact structures on the first side of the semiconductor layer and in contact with the gate all around transistors, and second contact structures on a second side of the semiconductor layer distant from the first semiconductor structure, and in contact with the first transistors and the gate all around transistors.

In some implementations, the first semiconductor structure further comprises a first interconnect layer comprising first interconnect structures coupled with the array of memory cells; and the second semiconductor structure further comprises a second interconnect layer comprising second interconnect structures coupled with the first contact structures.

In some implementations, the first semiconductor structure is hybrid bonded with the second semiconductor structure in a vertical direction, and the first interconnect structures are coupled with the second interconnect structures.

In some implementations, the second semiconductor structure further comprises: isolation structures extending through the semiconductor layer and between the transistors and/or the gate all around transistors.

In some implementations, the semiconductor layer is a monocrystal silicon layer having a thickness of less than 200 nm.

In some implementations, the memory device further comprises: a pad-out structure comprising: a third interconnect layer comprising third interconnect structures in contact with the second contact structures; and conductive pads in contact with the third interconnect structures.

In some implementations, one first transistor comprises: a first gate on the first side of the semiconductor layer and in contact with one first contact structure; and a second gate on the second side of the semiconductor layer and in contact with one second contact structure.

In some implementations, one of the first contact structures is in contact with a gate of a first gate all around transistor; and one of the second contact structures is in contact with a gate of a second gate all around transistor.

In some implementations, one of the first contact structures is in contact with a first source/drain terminal of one gate all around transistor; and one of the second contact structures is in contact with a second source/drain terminal of the one gate all around transistor.

In some implementations, the one of the first contact structures or the one of the second contact structures is coupled with a through interconnect structure extending through the semiconductor layer.

In some implementations, the first semiconductor structure is a 3D NAND array comprising an array of vertical NAND memory strings.

In some implementations, the first semiconductor structure is a DRAM cells array comprising an array of vertical transistors and vertical capacitors.

In some implementations, each gate all around transistor comprises: a channel in the semiconductor layer; a first source/drain at the first side of the semiconductor layer; a second source/drain at the second side of the semiconductor layer; a gate dielectric layer laterally surrounding the channel, the first source/drain, and the second source/drain; and a gate structure embedded in the gate dielectric layer and laterally surrounding the channel.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a cross-section of an exemplary 3D memory device, according to some aspects of the present disclosure.

FIG. 2A illustrates a schematic circuit diagram of an exemplary memory device, according to some aspects of the present disclosure.

FIG. 2B illustrates a schematic circuit diagram of an exemplary memory device, according to some aspects of the present disclosure.

FIG. 3 illustrates a schematic circuit diagram of an exemplary memory device, according to some aspects of the present disclosure.

FIG. 4 illustrates a schematic structural diagram of an exemplary 3D memory device in a cross-sectional side view, according to various implementations of the present disclosure.

FIGS. 5A-5C illustrate schematic structural diagrams of exemplary 3D memory devices in an enlarged cross-sectional side view, according to various implementations of the present disclosure.

FIG. 6 illustrates a block diagram of an exemplary system having a 3D memory device, according to some aspects of the present disclosure.

FIG. 7A illustrates a diagram of a memory card having a 3D memory device, according to some aspects of the present disclosure.

FIG. 7B illustrates a diagram of a solid-state drive (SSD) having a 3D memory device, according to some aspects of the present disclosure.

FIG. 8 illustrates a flow diagram of an exemplary method for forming a 3D memory device, according to s some aspects of the present disclosure.

FIGS. 9A-9F illustrate schematic cross-sectional views of an exemplary 3D memory device at certain fabricating stages of the method shown in FIG. 7, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

As semiconductor technology advances, three-dimensional (3D) memory devices, such as 3D NAND memory devices and 3D DRAM devices, keep increasing the memory density of the memory cell array. With the increase in the number of memory cells of the 3D architecture, the CMOS peripheral circuit needs more complex and size scaling. For example, a complementary metal-oxide-semiconductor wafer (“CMOS wafer” hereinafter) is bonded with a memory cell array wafer (“array wafer” hereinafter) to form a framework of the 3D memory device. Specifically, the disclosed 3D memory device can be a part of a non-monolithic 3D memory device, in which components (e.g., portions of the CMOS devices and the memory cell array device) are formed separately on different wafers and then bonded in a face-to-face manner.

In order to achieve optimization of area, the implementation of backside power delivery and gate-all-around (GAA) backside connections in CMOS technology is a crucial step in addressing the challenges of size compression and efficiency. By placing the pad-out layer on the backside of the CMOS wafer, the power delivery path is significantly shortened, reducing metal routing delays and enhancing overall chip performance. Additionally, integrating the peripheral circuits and the decoder circuits beneath the memory array allows for better layout optimization, leading to a significant (e.g., 20%-30%) reduction in CMOS area and improving cell efficiency. These advancements not only boost chip performance but also lower process complexity. By utilizing the backside power delivery and GAA connections, power transmission efficiency is improved, mitigating the bottlenecks caused by long power paths and increasing overall speed.

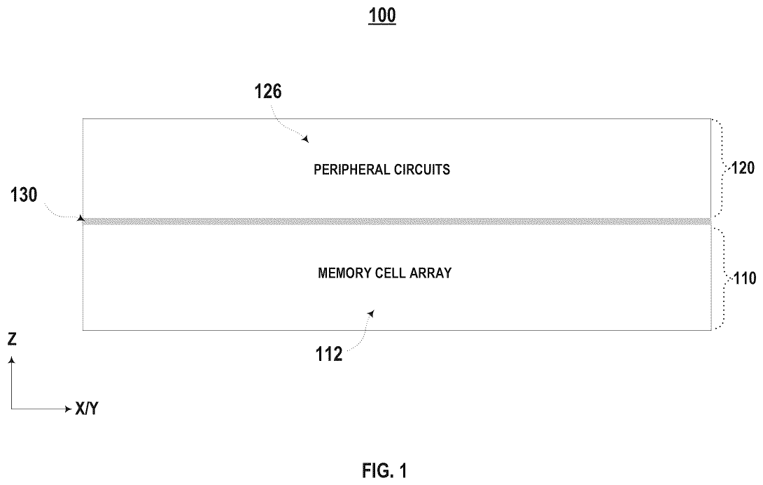

FIG. 1 illustrates a schematic view of a cross-section of a 3D memory device 100, according to some aspects of the present disclosure. In some implementations, 3D memory device 100 represents an example of a bonded chip. In some implementations, at least some of the components of 3D memory device 100 (e.g., first wafer/first semiconductor structure/array wafer 110 and second wafer/second semiconductor structure/CMOS wafer 120 as shown in FIG. 1) are formed separately on different substrates in parallel and then jointed to form a bonded chip (a process referred to herein as a “parallel process”). In some other implementations not shown, the 3D memory device can be a single wafer structure, in which the memory array and CMOS can be sequentially formed on a single substrate.

It is noted that X/Y and Z axes are added in FIG. 1 to further illustrate the spatial relationships of the components of a memory device. A substrate of a memory device, e.g., 3D memory device 100, includes two lateral surfaces (e.g., a top surface and a bottom surface) extending laterally in the X and Y directions (e.g., word line direction and bit line direction). As used herein, whether one component (e.g., a layer or a device) is “on,” “above,” or “below” another component (e.g., a layer or a device) of a memory device is determined relative to the substrate of the memory device in the Z direction (the vertical direction or thickness direction) when the substrate is positioned in the lowest plane of the memory device in the Z direction. The same notion for describing the spatial relationships is applied throughout the present disclosure.

3D memory device 100 can include a first semiconductor structure 110 including an array of memory cells (also referred to herein as a “memory cell array 112”). In some implementations, the memory cell array 112 includes an array of NAND Flash memory cells. For ease of description, a NAND Flash memory cell array may be used as an example for describing the memory cell array 112 in the present disclosure. In some implementations, the memory cell array 112 includes an array of DRAM cells. But it is understood that the memory cell array 112 is not limited to NAND Flash memory cell array or DRAM cell array, and may include any other suitable types of memory cell arrays, such as NOR Flash memory cell array, phase change memory (PCM) cell array, ferroelectric DRAM (FRAM) cell array, resistive memory cell array, magnetic memory cell array, spin transfer torque (STT) memory cell array, to name a few.

First semiconductor structure 110 can include a memory device in which the memory cells are provided in the form of an array of 3D memory cells. In some implementations, when the memory cell array 112 is a NAND memory cell array, the NAND memory cells can be organized as an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor. The 3D NAND memory string can be organized into pages or fingers, which are then organized into blocks in which each NAND memory cell is coupled to a separate line called a bit line (BL). All cells with the same vertical position in the NAND memory cell can be coupled through the control gates by a word line (WL). In some implementations, a memory plane contains a certain number of blocks that are coupled through the same bit line. First semiconductor structure 110 can include one or more memory planes.

In some other implementations, when the memory cell array 112 is a DRAM cell array, each DRAM cell can include a vertical transistor and a storage unit coupled to the vertical transistor. The vertical transistors can be vertical metal-oxide-semiconductor field-effect transistors (MOSFETs), and the storage units can be capacitors for storing charges as the binary information stored by the respective DRAM cells. In some other implementations, when the memory cell array 112 is a PCM cell array, the storage unit can be a PCM element (e.g., including chalcogenide alloys) for storing binary information of the respective PCM cell based on the different resistivities of the PCM element in the amorphous phase and the crystalline phase. In some other implementations, when the memory cell array 112 is a FRAM cell array, the storage unit can be a ferroelectric capacitor for storing binary information of the respective FRAM cell based on the switch between two polarization states of ferroelectric materials under an external electric field.

As shown in FIG. 1, 3D memory device 100 can also include one or more peripheral circuits 126 of the memory cell array form in a second semiconductor structure 120 to perform all the read/program (write)/erase operations. The one or more peripheral circuits 126 (a.k.a. control and sensing circuits) can include any suitable digital, analog, and/or mixed-signal circuits used for facilitating the operations of the memory cell array. For example, the one or more peripheral circuits 126 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The one or more peripheral circuits 126 in second semiconductor structure 120 can use CMOS technology, e.g., which can be implemented with logic processes in any suitable technology nodes. In some implementations, second semiconductor structure 120 does not include any memory cell. In other words, second semiconductor structure 120 only includes peripheral circuits 126, but not the memory cell array 112, according to some implementations. As a result, memory cell array 112 can be only included in first semiconductor structure 110, but not in second semiconductor structure 120.

As shown in FIG. 1, first semiconductor structure 110 and second semiconductor structure 120 are stacked in two different planes, according to some implementations. In some implementations, memory cell array 112 can be arranged in first semiconductor structure 110, peripheral circuits 126 can be arranged in second semiconductor structure 120, and can be stacked over first semiconductor structure 110 to reduce the planar size of 3D memory device 100, compared with memory devices in which all the peripheral circuits are disposed in a same plane.

As shown in FIG. 1, 3D memory device 100 further includes a bonding interface 130 vertically between first semiconductor structure 110 and second semiconductor structure 120. Bonding interface 130 can be an interface between two semiconductor structures formed by any suitable bonding technologies as described below in detail, such as hybrid bonding, anodic bonding, fusion bonding, transfer bonding, adhesive bonding, and eutectic bonding, to name a few. In some implementations, as shown in FIG. 1, second semiconductor structure 120 is bonded to first semiconductor structure 110 on opposite sides thereof.

As described below in detail, first semiconductor structure 110 and second semiconductor structure 120 can be fabricated separately (and in parallel in some implementations) by the parallel process, such that the thermal budget of fabricating one of first and second semiconductor structures 110 and 120 does not limit the processes of fabricating another one of first and second semiconductor structures 110 and 120. Moreover, a large number of interconnects (e.g., bonding contacts and/or inter-layer vias (ILVs)/through substrate vias (TSVs)) can be formed across bonding interface 130 to make direct, short-distance (e.g., micron- or submicron-level) electrical connections between first and second semiconductor structures 110 and 120, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among memory cell array 112 and peripheral circuits 126 in first and second semiconductor structures 110 and 120 can be performed through the interconnects (e.g., bonding contacts and/or ILVs/TSVs) across bonding interface 130. By vertically integrating first and second semiconductor structures 110 and 120, the chip size can be reduced, and the memory cell density can be increased.

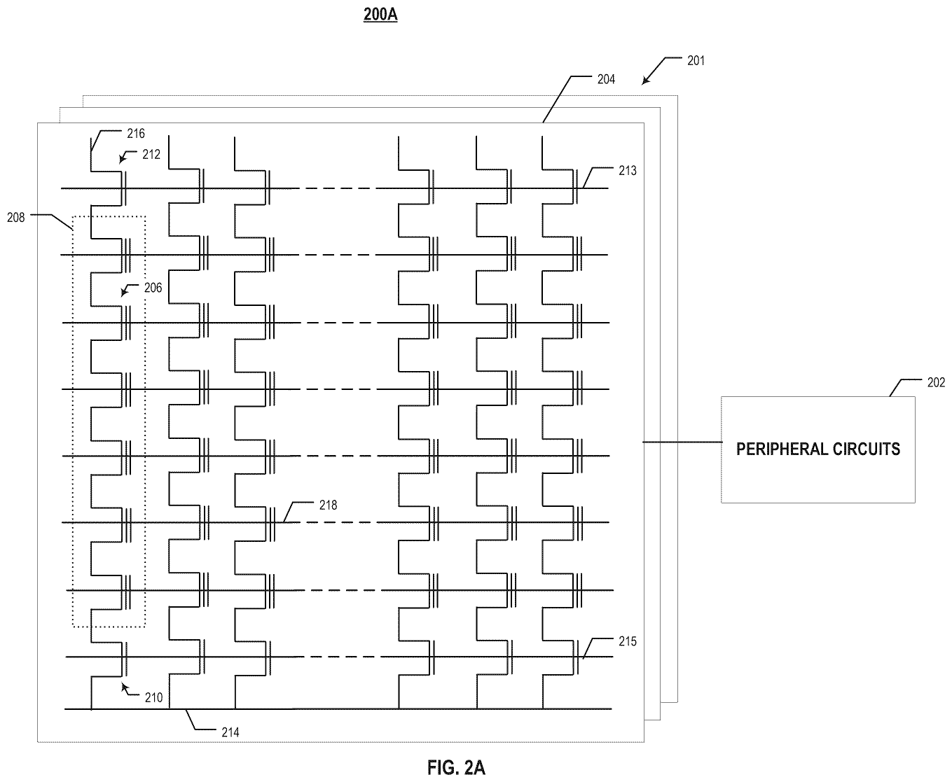

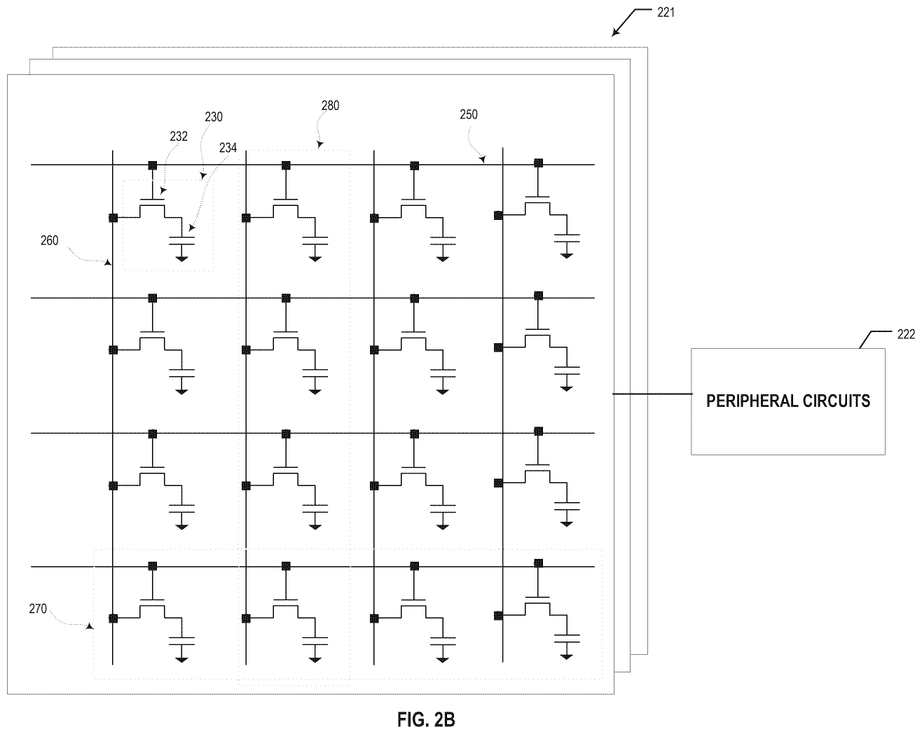

FIG. 2A illustrates a schematic circuit diagram of a memory device 200A including peripheral circuits, according to some aspects of the present disclosure. Memory device 200A can include one or more NAND memory cell arrays 201 and peripheral circuits 202 coupled to the one or more NAND memory cell arrays 201. In each NAND memory cell array 201, the memory cells 206 are provided in the form of an array of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2A, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2A, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. Each word line 218 can include a plurality of control gates (gate electrodes) at each memory cell 206 and a gate line coupling the control gates.

FIG. 2B illustrates a schematic circuit diagram of a memory device 200B including peripheral circuits, according to some aspects of the present disclosure. Memory device 200B can include one or more DRAM cell arrays 221 and peripheral circuits 222 coupled to the one or more DRAM cell arrays 221. In some implementations, the DRAM cells 230 can be arranged in a two-dimensional (2D) array having rows and columns.

In some implementations, the memory device 200B can include word lines 250 coupling the DRAM cell array 221 to the peripheral circuits 222 for controlling the switch of vertical transistors 232 in DRAM cells 230 located in a row, as well as bit lines 260 coupling the DRAM cell array 221 to the peripheral circuits 222 for sending data to and/or receiving data from the capacitors 234 in DRAM cells 230 located in a column. That is, each word line 250 is coupled to a respective row of DRAM cells 230, and each bit line 260 is coupled to a respective column of DRAM cells 230. In some implementations, the gate of vertical transistor 232 is coupled to word line 250, one of the source and the drain of vertical transistor 232 is coupled to bit line 260, the other one of the source and the drain of vertical transistor 232 is coupled to one electrode of capacitor 234, and the other electrode of capacitor 234 is coupled to the ground.

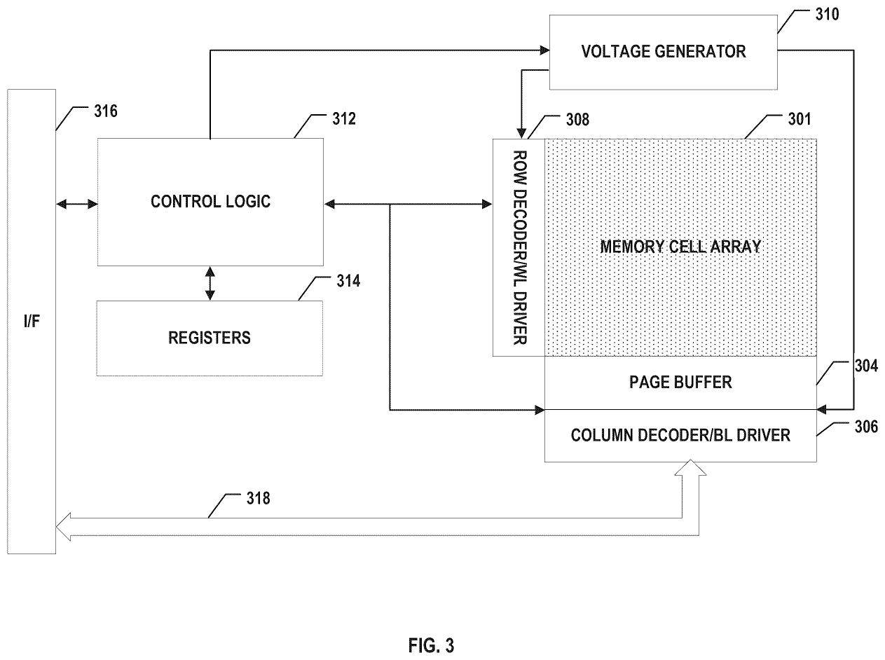

Referring to FIG. 2A, the peripheral circuits 202 can be coupled to NAND memory cell array 201 through bit lines 216, word lines 218, source lines 214, SSG lines 215, and DSG lines 213. Referring to FIG. 2B, the peripheral circuits 222 can be coupled to DRAM cell array 221 through bit lines 260 and word lines 250. As described above, the peripheral circuits 202/222 can include any suitable circuits for facilitating the operations of memory cell array 201/221 by applying and sensing voltage signals and/or current signals through various lines to and from each target memory cell 206/230. The peripheral circuits 202/222 can include various types of peripheral circuits formed using CMOS technologies. For example, FIG. 3 illustrates a memory device 300 comprising a memory cell array 301 and peripheral circuits. The peripheral circuits can be peripheral circuits 202/222 shown in FIGS. 2A and 2B, and can include a page buffer 304, a column decoder/bit line driver 306, a row decoder/word line driver 308, a voltage generator 310, control logic 312, registers 314, an interface (I/F) 316, and a data bus 318. It is understood that in some examples, additional peripheral circuits 202/222 may be included as well.

In some implementations, the page buffer 304 can be configured to buffer data read from or programmed to memory cell array 201/221 according to the control signals of control logic 312. In one example, page buffer 304 may store one page of program data (write data) to be programmed into NAND memory cell array 201 or one page 270 of DRAM cell array 221. In another example, page buffer 304 also performs program verify operations to ensure that the data has been properly programmed into memory cells 206 or DRAM cells 230 coupled to selected word lines 218/250.

Row decoder/word line driver 308 can be configured to be controlled by control logic 312 and select block 204/224 of memory cell array 201/221 and a word line 218/250 of selected block 204/224. Row decoder/word line driver 308 can be further configured to drive memory cell array 201/221. For example, row decoder/word line driver 308 may drive memory cells 206/230 coupled to the selected word line 218/250 using a word line voltage generated from voltage generator 310.

Column decoder/bit line driver 306 can be configured to be controlled by control logic 312 and select one or more 3D NAND memory strings 208 or columns 280 of DRAM cells 230 by applying bit line voltages generated from voltage generator 310. For example, column decoder/bit line driver 306 may apply column signals for selecting a set of N bits of data from page buffer 304 to be output in a read operation.

Control logic 312 can be coupled to each peripheral circuit 202/222 and configured to control operations of peripheral circuits 202/222. Registers 314 can be coupled to control logic 312 and include status registers, command registers, and address registers for storing status information, command operation codes (OP codes), and command addresses for controlling the operations of each peripheral circuit 202/222.

Interface 316 can be coupled to control logic 312 and configured to interface memory cell array 201/221 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of peripheral circuits 202/222.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201/221. In some implementations, voltage generator 310 is part of a voltage source that provides voltages at various levels of different peripheral circuits 202/222. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations.

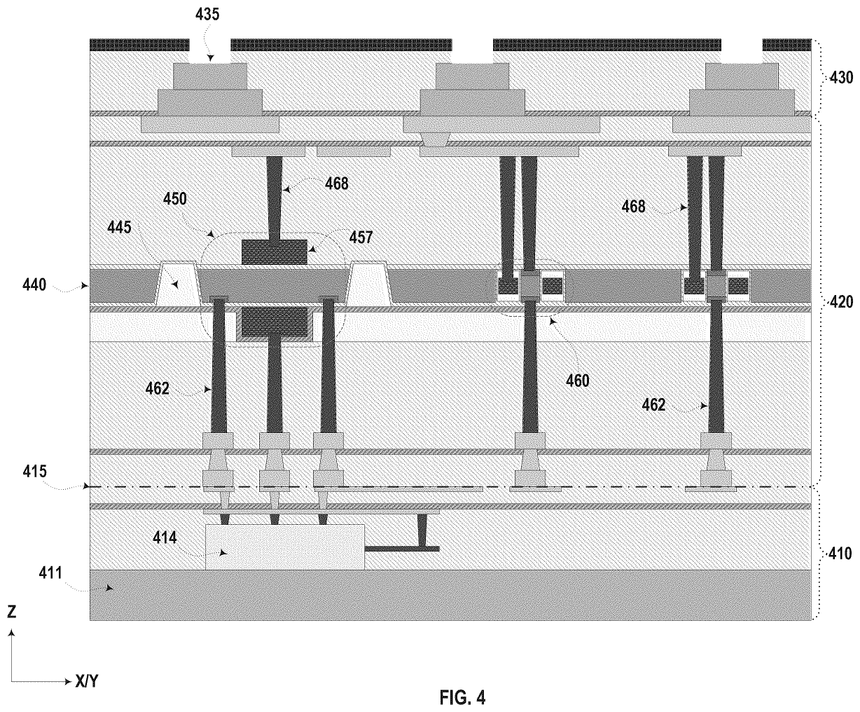

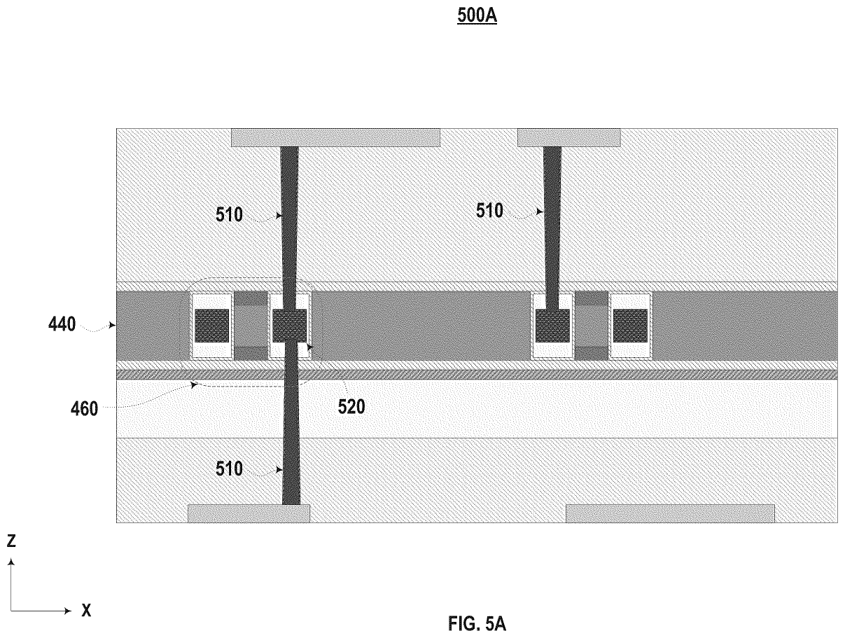

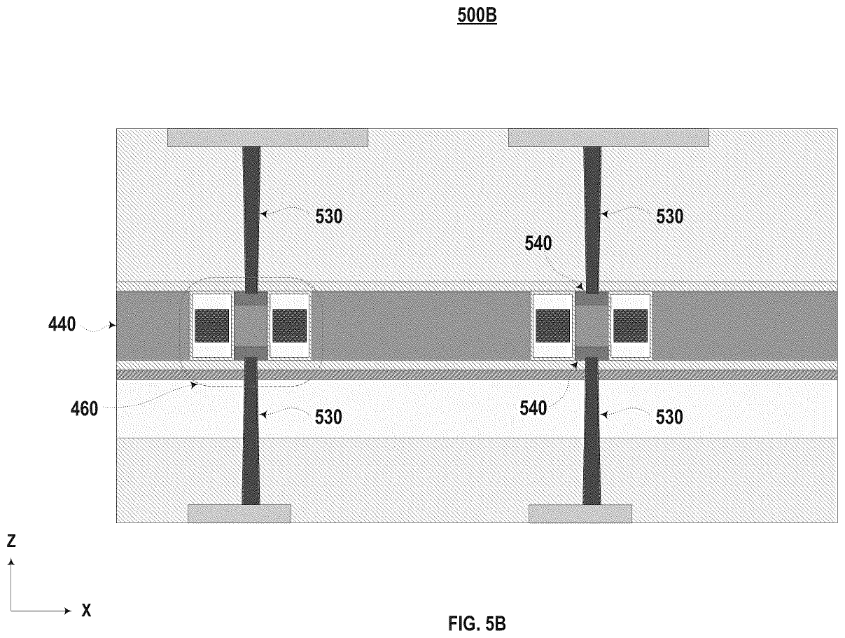

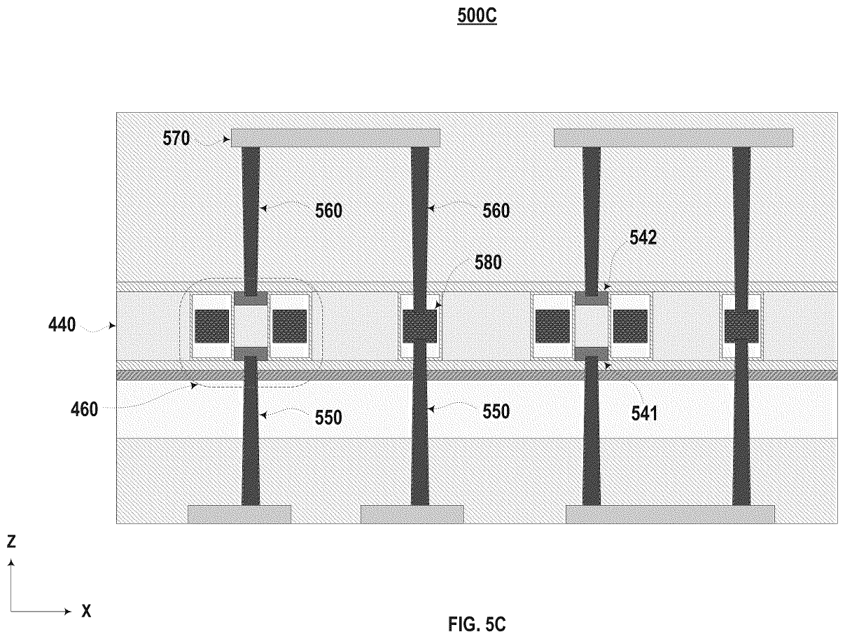

FIG. 4 illustrates a schematic structural diagram of an exemplary 3D memory device in a cross-sectional side view, according to some implementations of the present disclosure. FIGS. 5A-5C illustrate schematic structural diagrams of a portion of the exemplary 3D memory device in a cross-sectional side view, according to various implementations of the present disclosure. It is noted that X, Y, and Z axes are included in FIGS. 4 and 5A-5C to further illustrate the spatial relationship of the components in 3D memory devices.

As shown in FIG. 4, in some implementations, 3D memory device 400 is a bonded chip including a first semiconductor structure 410 and a second semiconductor structure 420 stacked over first semiconductor structure 410. The first semiconductor structure 410 and the second semiconductor structure 420 are jointed at a bonding interface 415 therebetween, according to some implementations.

As shown in FIG. 4, first semiconductor structure 410 can include semiconductor layer 411, which can include silicon (e.g., single crystalline silicon, c-Si, or poly crystalline silicon, etc.), silicon germanium (SiGe), gallium arsenide (GaAs), germanium (Ge), silicon-on-insulator (SOI), or any other suitable materials. In some implementations, first semiconductor structure 410 of 3D memory device 400 further includes a memory cell array 414. The memory cell array 414 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the first semiconductor structure 410 of 3D memory device 400 further includes an interconnect layer above the memory cell array 414 to transfer electrical signals from/to the memory cell array 414. The interconnect layer can include a plurality of interconnects (also referred to herein as contacts), including lateral interconnect lines and vertical interconnect access (VIA) contacts. As used herein, the term interconnects can broadly include any suitable types of interconnects, such as middle-end-of-line (MEOL) interconnects and back-end-of-line (BEOL) interconnects. The interconnect layer can further include one or more interlayer dielectric (ILD) layers (a.k.a. intermetal dielectric (IMD) layers) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

In some implementations, the first semiconductor structure 410 of 3D memory device 400 can further include a bonding layer at bonding interface 415 and above the interconnect layer. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. The bonding contacts and surrounding dielectrics in bonding layer can be used for hybrid bonding.

As shown in FIG. 4, the second semiconductor structure 420 of 3D memory device 400 can include a semiconductor layer 440, which can include Si, SiGe, GaAs, Ge, or any other suitable semiconductor materials. In some implementations, the semiconductor layer 440 can be monocrystal silicon layer. In some implementations, a thickness of the semiconductor layer 440 can be less than 200 nm or less than 100 nm. The second semiconductor structure 420 of 3D memory device 400 can include one or more peripheral circuits on semiconductor layer 440. In some implementations, the one or more peripheral circuits can include any suitable peripheral circuits 202/222 discussed above.

In some implementations, the one or more peripheral circuits can include a plurality of first transistors 450 on the semiconductor layer 440. In some implementations, isolation regions (e.g., STIs) 445 and doped regions (e.g., source regions and drain regions of the transistors, not shown) can be formed in the semiconductor layer 440. In some implementations, the gate structure of the first transistor 450 is located on a first side of semiconductor layer 440. In some implementations, the first transistor 450 further includes a second gate structure 457 located on a second side of semiconductor layer 440. In some implementations, the one or more peripheral circuits can further include a plurality of gate-all-around (GAA) transistors 460 located in the semiconductor layer 440. In some implementations, a portion of the semiconductor layer 440 laterally surrounded by a ring-type gate structure functions as the channel of the GAA transistor 460, two doped regions at the upper and lower surfaces of the portion of the semiconductor layer 440 function as the source region and drain region of the GAA transistor 460.

In some implementations, the second semiconductor structure 420 of 3D memory device 400 can further includes a front-side interconnect layer on the plurality of first transistors 450 and the GAA transistors 460 to transfer electrical signals. The front-side interconnect layer can include a plurality of first contact structures 462 on the first side of the semiconductor layer 440. The first contact structures 462 and the first transistors 450 are disposed at the same side of semiconductor layer 411 and thus, viewed as front-side contact structures. The first contact structures 462 can be formed by any suitable MEOL method and electrically connected to the first transistors 450 and the GAA transistors 460. For example, the first contact structures 462 can include source/drain contacts and/or gate contacts in contact with the source/drain regions and/or gate structures of the first transistors 450 and the GAA transistors 460.

In addition to the front-side interconnect layer, the second semiconductor structure 420 of 3D memory device 400 can further include a back-side interconnect layer on a second side of the semiconductor layer 440. As shown in FIG. 4, the back-side interconnect layer can include a plurality of second contact structures 468 on the second side of the semiconductor layer 440. The second contact structures 468 and first transistors 450 can be disposed at opposite sides of the semiconductor layer 440 and thus, viewed as back-side contact structures. In some implementations, the second contact structures 468 can be formed by any suitable BEOL method and electrically connected to the first transistors 450 and the GAA transistors 460. For example, the second contact structures 468 can include source/drain contacts and/or gate contacts in contact with the source/drain regions and/or gate structures of the GAA transistors 460, and second gate contacts in contact with the second gate structure 457 of the first transistors 450.

In some implementations, the first contact structures 462 and the second contact structures 468 can include any suitable types of contacts and/or pads. In some implementations, the first contact structures 462 and the second contact structures 468 can include VIA contacts, wall-shaped contacts extending laterally, one or more conductive layers, such as a metal layer (e.g., W, Co, Cu, or Al) or a silicide layer surrounded by an adhesive layer (e.g., titanium nitride (TiN)), etc. In some implementations, the first contact structures 462 and the second contact structures 468 may further include a spacer (e.g., a dielectric layer) to electrically separate the one or more of the first contact structures 462 and the second contact structures 468.

Similar to the first semiconductor structure 410, the second semiconductor structure 420 of 3D memory device 400 can also include a bonding layer at bonding interface 415. Bonding layer can include a plurality of bonding contacts and dielectrics electrically isolating bonding contacts. Bonding contacts can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts and surrounding dielectrics in bonding layer can be used for hybrid bonding. Bonding contacts of the first semiconductor structure 410 are in contact with bonding contacts of the second semiconductor structure 420 at bonding interface 415, according to some implementations.

As shown in FIG. 4, the second semiconductor structure 420 can be bonded on top of the first semiconductor structure 410 in a face-to-face manner at bonding interface 415. In some implementations, bonding interface 415 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 415 is the place at which the bonding layer of the first semiconductor structure 410 and the bonding layer of the second semiconductor structure 420 are met and bonded. The bonding contacts of the bonding layers of the first and second semiconductor structures 410 and 420 can be in electrical contact with each other, such that the one or more peripheral circuits in the second semiconductor structure 420 can be coupled with the memory cell array 414 in the first semiconductor structure 410.

As shown in FIG. 4, in some implementations, the 3D memory device 400 can further include a pad-out structure 430 on the back-side interconnect layer of the second semiconductor structure 420. The pad-out structure 430 can include a plurality of conductive pads 435 and an interconnect layer comprising interconnect structures coupled between the conductive pads 435 and the second contact structures 468 to transfer electrical signals. The interconnect layer of the pad-out structure 430 can include a plurality of interconnects, including lateral interconnect lines and VIA contacts, formed by any suitable BEOL method. The interconnect layer of the pad-out structure 430 can further include one or more ILD layers in which the interconnect lines and VIA contacts can form. The interconnect lines and VIA contacts in the interconnect layer can include conductive materials including, but not limited to, W, Co, Cu, or Al, silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

FIG. 5A illustrates a cross-sectional structural diagram of a portion of the 3D memory device 400 including gate contacts 510 in contact with the gate structures 520 of the GAA transistors 460. As shown in FIG. 5A, according to some implementations, the gate contacts 510 can be located in either the front-side interconnect layer or the back-side interconnect layer or both. That is, the gate structures 520 of the GAA transistors 460 can be electrically connected from any one or both sides of the semiconductor layer 440.

FIG. 5B illustrates a cross-sectional structural diagram of a portion of the 3D memory device 400 including source/drain contacts 530 in contact with the source/drain regions 540 of the GAA transistors 460. As shown in FIG. 5B, according to some implementations of the present disclosure, for each GAA transistor 460, one of the source/drain contacts 530 can be located in the front-side interconnect layer, and the other one of the source/drain contacts 530 can be located in the back-side interconnect layer. That is, the source/drain contacts 530 of the GAA transistors 460 can be electrically connected from both sides of the semiconductor layer 440, respectively.

FIG. 5C illustrates a cross-sectional structural diagram of a portion of the 3D memory device 400 including source/drain contacts 550/560 in contact with the source/drain regions 540 of the GAA transistors 460. As shown in FIG. 5C, according to some implementations, for each GAA transistor 460, a first source/drain terminal 541 can be coupled with one of the source/drain contacts 550 located in the front-side interconnect layer, and a second source/drain terminal 542 can be coupled with one of the source/drain contacts 560 located in the back-side interconnect layer. The second source/drain terminal 542 can then be coupled back to the front-side of the semiconductor layer 440 by a bridge structure 570, a source/drain contacts 560 in the back-side interconnect layer, a through interconnect structure 580 extending through the semiconductor layer 440, and a source/drain contacts 550 in the front-side interconnect layer. That is, both of the source/drain terminals of the GAA transistors 460 can be electrically connected from a same side of the semiconductor layer 440.

Although exemplary 3D memory structures 400, 500A, 500B and 500C are shown in FIGS. 4 and 5A-5C, it is understood that by varying the relative positions of first and second semiconductor structures 410 and 420, the usage of various interconnects, contacts, and/or the pad-out locations (e.g., through first semiconductor structure 410 and/or second semiconductor structure 420), any other suitable architectures of 3D memory devices may be applicable in the present disclosure without further detailed elaboration.

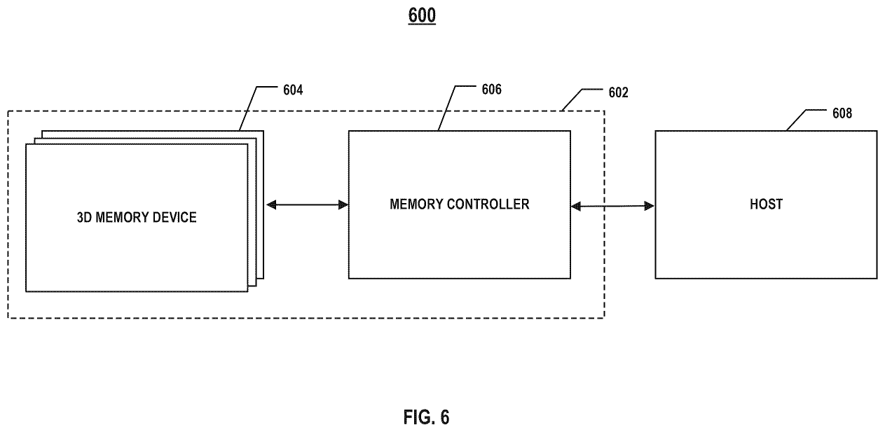

FIG. 6 illustrates a block diagram of an exemplary system 600 having a 3D memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more 3D memory devices 604 and a memory controller 606. Host 608 can be a processor of an electronic device, such as a central processing unit (CPU), or a system-on-chip (SoC), such as an application processor (AP). Host 608 can be configured to send or receive data to or from 3D memory device 604.

3D memory device 604 can be any 3D memory devices disclosed herein, such as 3D memory devices 100/400, shown in FIGS. 1 and 4. In some implementations, each 3D memory device 604 includes a NAND Flash memory and/or a DRAM memory. Memory controller 606 (a.k.a., a controller circuit) is coupled to 3D memory device 604 and host 608 and is configured to control 3D memory device 604, according to some implementations. Memory controller 606 can manage the data stored in 3D memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

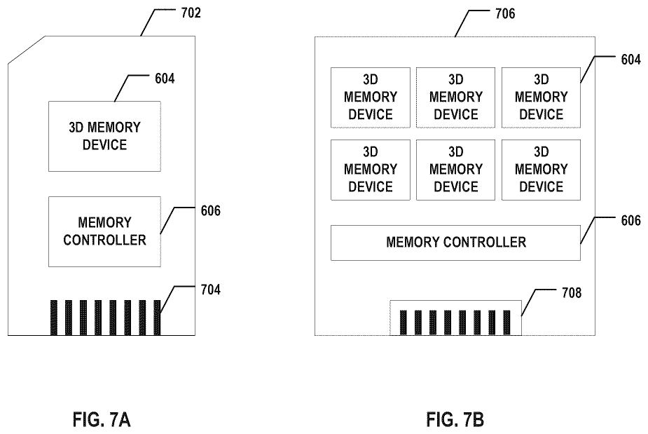

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single 3D memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 electrically coupling memory card 702 with a host (e.g., host 608 in FIG. 6). In another example as shown in FIG. 7B, memory controller 606 and multiple 3D memory devices 604 may be integrated into an SSD 706. SSD 706 can further include an SSD connector 708 electrically coupling SSD 706 with a host (e.g., host 608 in FIG. 6). In some implementations, the storage capacity and/or the operation speed of SSD 706 is greater than those of memory card 702.

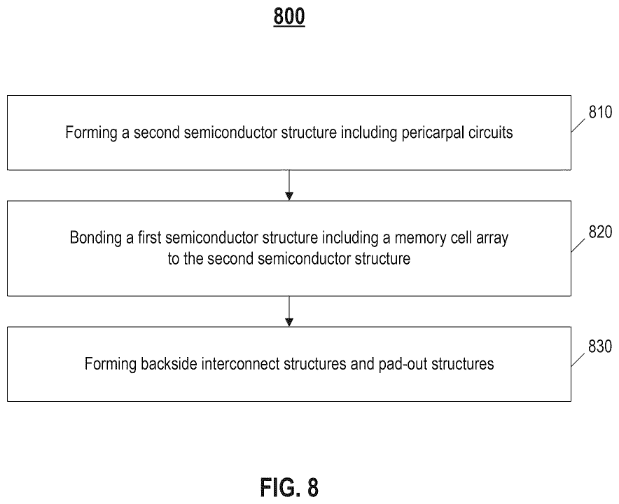

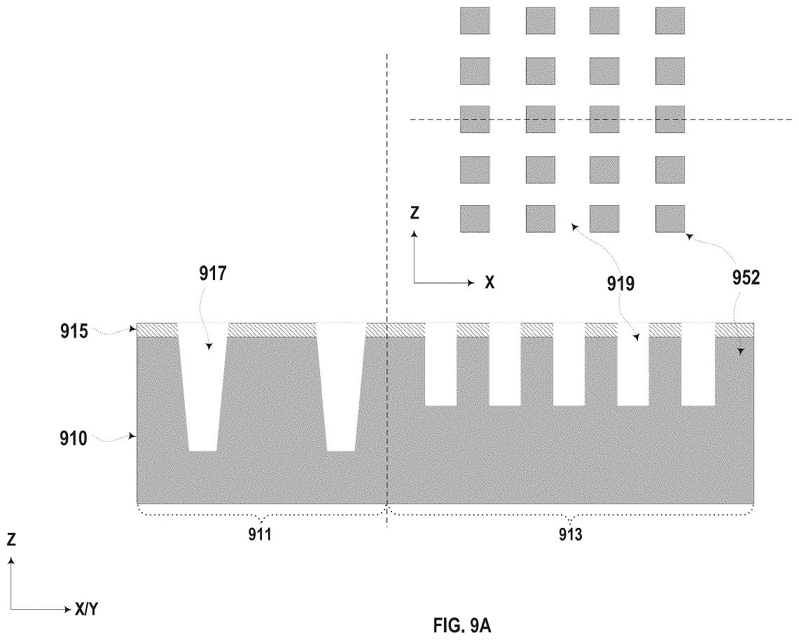

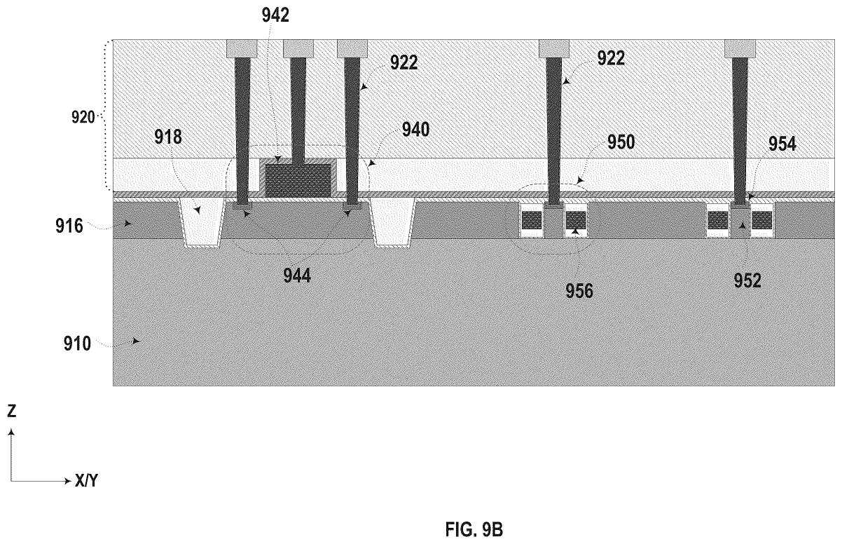

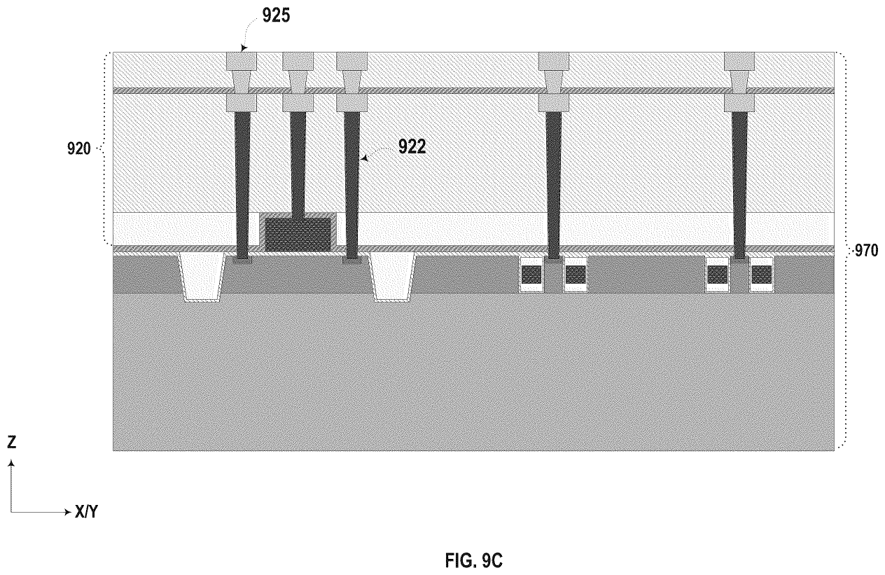

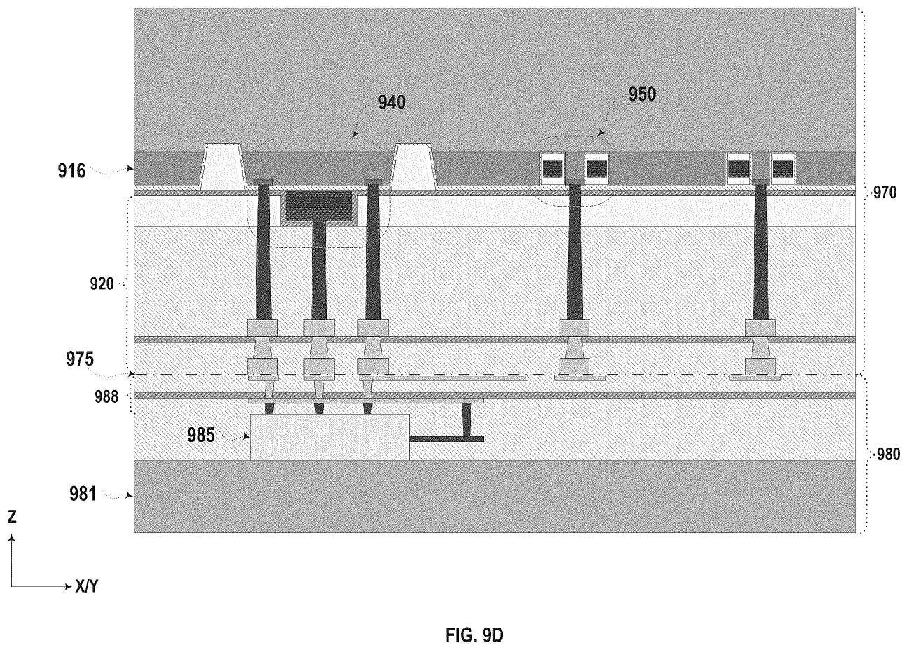

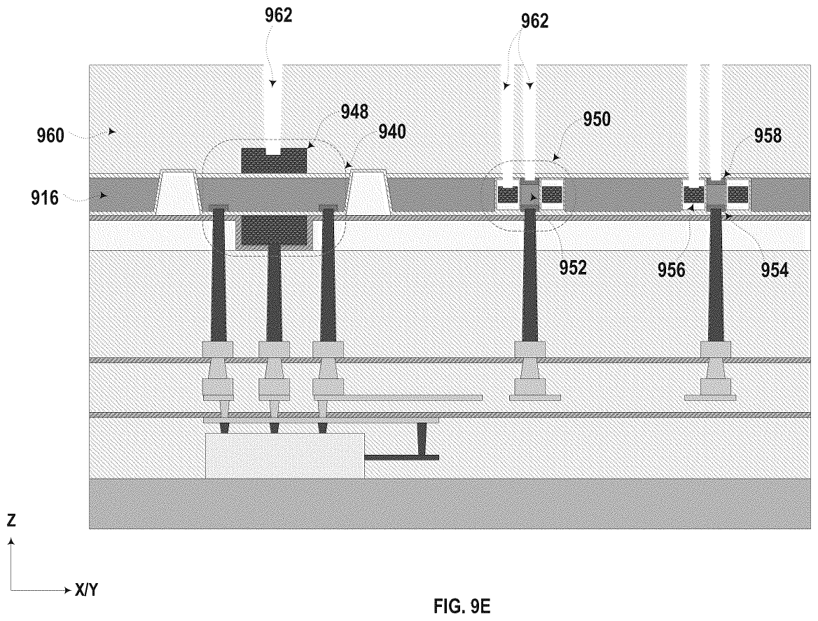

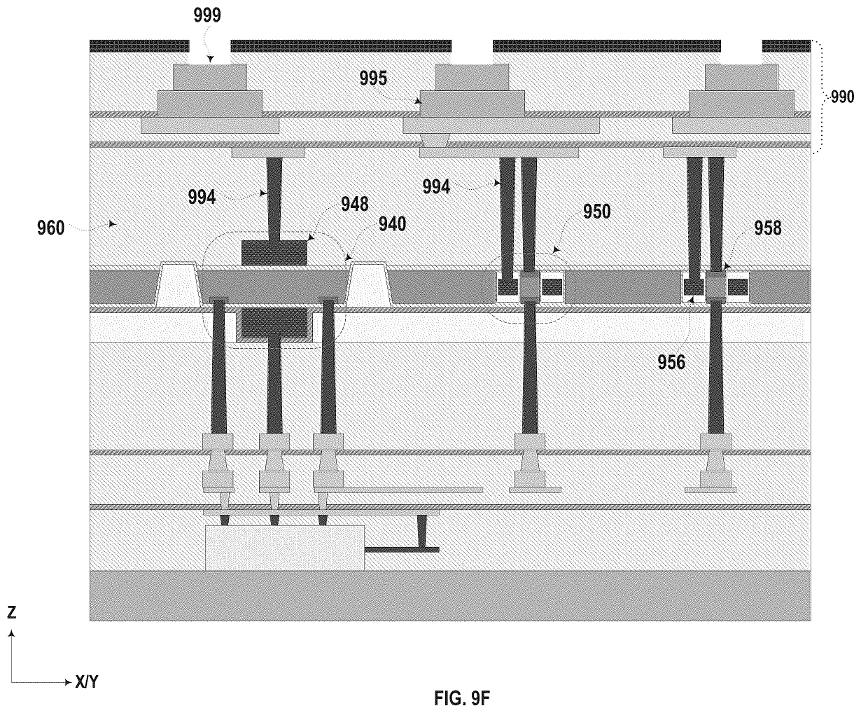

Referring to FIG. 8, a flow diagram of an exemplary method for forming a 3D memory device is illustrated in accordance with some implementations of the present disclosure. It should be understood that the operations shown in FIG. 8 are not exhaustive and that other operations can be performed as well before, after, or between any of the illustrated operations. Further, some of the operations may be performed simultaneously, or in a different order than shown in FIG. 8. FIGS. 9A-9F illustrate schematic cross-sectional views of an exemplary 3D memory device at certain fabricating stages of the method shown in FIG. 8 according to some implementations of the present disclosure.

Referring to FIG. 8, method 800 can start at operation 810, in which a second semiconductor structure including peripheral circuits can be formed. In some implementations, the peripheral circuits include a plurality of first transistors and GAA transistors. The plurality of first transistors are formed at a first side of a semiconductor layer, and the GAA transistors are form in the semiconductor layer. The second semiconductor structure further includes first contact structures on the first side of the semiconductor layer. FIGS. 9A-9C illustrate schematic cross-sectional views of an exemplary 3D structure at certain fabricating stages of the operation 810, according to some implementations of the present disclosure.

In some implementations, operation 810 can include forming trenches in a semiconductor layer. The semiconductor layer 910 can include Si, SiGe, GaAs, Ge, or any other suitable semiconductor materials. In some implementations, the semiconductor layer 910 can be monocrystal silicon layer. As shown in FIG. 9A, the semiconductor layer 910 can be patterned to form a plurality of first trenches 917 in a first region 911, and a plurality of second trenches 919 in a second region 913. In some implementations, the depth of the first trenches 917 can be greater than the depth of the second trenches 919. In some implementations, the second trenches 919 can extend laterally in both the first and second directions (i.e., the X and Y directions), and vertically in a substantially straight in the vertical direction (i.e., the Z direction) to form a plurality of semiconductor pillars 952 each extending the vertical direction. In some implementations, the first trenches 917 and the second trenches 919 can be formed by forming a mask layer 915 over semiconductor layer 910 and patterning the mask layer 915 using, e.g., photolithography, to form openings corresponding to the multiple trenches in the patterned mask layer 915. One or more suitable etching processes, e.g., dry etch and/or wet etch, can be performed to remove portions of semiconductor layer 910 exposed by the openings until the first trenches 917 and the second trenches 919 reach the desired depths. The mask layer 915 can be removed after the formation of the first trenches 917 and the second trenches 919.

In some implementations, operation 810 can further include forming doped regions in the semiconductor layer. As shown in FIG. 9B, a lightly doped semiconductor layer 916 can be formed in the upper portion of the semiconductor layer 910. In some implementations, the depth of the lightly doped semiconductor layer 916 can be equal to or greater than the depth of the semiconductor pillars 952. In some implementations, a first amount of n-type or p-type impurities (dopants) can be introduced into an upper portion of the semiconductor layer 910 to create an n-type or p-type doped region having a first dopant concentration. As shown in FIG. 9B, forming transistors can further include forming a plurality of heavily doped regions 944 and 954 in the semiconductor layer 910. In some implementations, a second amount of the same type of impurities (dopants) can be introduced into multiple portions of the lightly doped semiconductor layer 916 to create heavily doped regions 944 and 954 having a second dopant concentration greater than the first dopant concentration. The lightly doped semiconductor layer 916 can be used as the channels of the formed transistors. The heavily doped regions 944 can be used as the source and drain regions of the first transistors 940, and the heavily doped regions 954 can be used as the source or drain regions of the GAA transistors 950. The doping processes of forming the lightly doped semiconductor layer 916 and the heavily doped regions 944 and 954 can include one or more of ion implantation, diffusion, in-situ doping, activation annealing, etc.

In some implementations, operation 810 can further include forming gate structures 942 of the first transistors 940 on a first side of the lightly doped semiconductor layer 916, and forming all-around gate structures 956 in the lightly doped semiconductor layer 916 each surrounding a corresponding semiconductor pillar 952. In some implementations, a gate dielectric layer can be deposited to cover the exposed surfaces of the lightly doped semiconductor layer 916 and the heavily doped regions 944, 954, including the inner surfaces of the trenches 917 and 919. The gate dielectric layer can include any suitable dielectric materials, such as silicon oxide, silicon nitride, silicon oxynitride, or high-k dielectrics. A conductive gate material can be deposited on the gate dielectric layer between the heavily doped regions 944 to form the gate electrodes of the first transistors 940, and in the second trenches 919 to form the electrodes of the GAA transistors 950. The gate electrodes can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

In some implementations, operation 810 can further include forming trench isolations (e.g., shallow trench isolations (STIs)) 918 in first trenches 917. The trench isolations 918 can include any suitable dielectric materials, such as silicon oxide, silicon nitride, silicon oxynitride, or high-k dielectrics.

As shown in FIG. 9B, operation 810 can further include forming a first interconnect layer 920 including a plurality of first contact structures 922. As shown in FIG. 9C, forming the first interconnect layer 920 can further include forming a first bonding layer including a plurality of first bonding contacts 925. In some implementations, forming the first interconnect layer 920 can include forming one or more ILD layers, forming vertical openings (e.g., by wet etching and/or dry etching) in the one or more ILD layers, and filling the openings with conductor materials using ALD, CVD, PVD, any other suitable processes, or any combination thereof to form the first contact structures 922. The first contact structures 922 and the first bonding contacts 925 can include interconnect lines and VIA contacts including conductive materials including, but not limited to, W, Co, Cu, or Al, silicides, or any combination thereof. The ILD layers in the first interconnect layer 920 can include dielectric materials including, but not limited to, silicon oxide, silicon nitride, silicon oxynitride, low dielectric constant (low-k) dielectrics, or any combination thereof.

In some implementations, each first contact structure 922 and/or the first bonding contacts 925 can include multiple sub-contacts formed in the multiple ILD layers. For example, the multiple sub-contacts can include one or more contacts, single-layer/multi-layer vias, conductive lines, plugs, pads, etc., formed in multiple contact-forming processes. For example, fabrication processes to form multiple sub-contacts can include forming one or more conductive layers and one or more contact layers in the corresponding ILD layers. The conductive layers and the conductor contact layers can be formed by any suitable known MEOL or BEOL methods. In some implementations, first contact structures 922 can include source/drain contacts electrically connected to the source/drain regions 944/954 of the first transistors 940 and the GAA transistors 950, and can further include gate contacts electrically connected to the gate structures 942/952 of the first transistors 940 and the GAA transistors 950. By connecting the first transistors 940 and the GAA transistors 950 through the first interconnect layer 920, the second semiconductor structure 970 including one or more peripheral circuits can be formed.

Referring back to FIG. 8, method 800 proceeds to operation 820, in which a first semiconductor structure including a memory cell array can be bonded to the second semiconductor structure including the peripheral circuits. FIG. 9D illustrates a schematic cross-sectional view of the exemplary 3D structure after operation 820, according to some implementations of the present disclosure.

In some implementations, as shown in FIG. 9D, a first semiconductor structure 980 including a memory cell array 985 on a substrate 981, and an interconnect layer 988 on the memory cell array 985 can be provided. In some implementations, the substrate 981 can be any suitable semiconductor substrate having any suitable structure, such as a monocrystalline single-layer substrate, a polycrystalline silicon (polysilicon) single-layer substrate, a polysilicon and metal multi-layer substrate, etc. In some implementations, memory cell array 985 can be any suitable type of memory cell array, such as NAND Flash memory cell array, DRAM cell array, NOR Flash memory cell array, PCM cell array, FRAM cell array, resistive memory cell array, magnetic memory cell array, STT memory cell array, etc.

In some implementations, the interconnect layer 988 is formed above the memory cell array 985 to transfer electrical signals from/to the memory cell array 985. The interconnect layer 988 can include a plurality of interconnects, including lateral interconnect lines, VIA contacts, and bonding contacts, formed by any suitable MEOL or BEOL processes. The interconnect layer 988 can further include one or more ILDs in which the interconnects can form. The interconnects in the interconnect layer can include conductive materials including, but not limited to, W, Co, Cu, or Al, silicides, or any combination thereof. The ILD layers in the interconnect layer 988 can include dielectric materials including, but not limited to, silicon oxide, silicon nitride, silicon oxynitride, low dielectric constant (low-k) dielectrics, or any combination thereof.

As shown in FIG. 9D, the first semiconductor structure 980 and the second semiconductor structure 970 can be bonded in a face-to-face manner. That is, the second semiconductor structure 970 can be flipped upside down, and bonded to the first semiconductor structure 980. The bonding can include hybrid bonding. As such, the first semiconductor structure 980 and the second semiconductor structure 970 can be bonded together in a face-to-face manner at bonding interface 975, according to some implementations. In some implementations, a treatment process, e.g., a plasma treatment, a wet treatment, and/or a thermal treatment, is applied to the bonding surfaces of the first semiconductor structure 980 and the second semiconductor structure 970 prior to the bonding. After the bonding, corresponding first bonding contacts 925 in the first interconnect layer 920 of the second semiconductor structure 970 and the bonding contacts in the interconnect layer 988 of the first semiconductor structure 980 are aligned and in contact with one another, such that memory cell array 985 can be electrically connected to the first transistors 940 and the GAA transistors 950 of the peripheral circuits.

Referring back to FIG. 8, method 800 proceeds to operation 830, in which the semiconductor layer in the second semiconductor structure can be thinned, second gate structures of the first transistors and source/drain regions of the GAA transistor can be formed, second interconnect structures can be formed on a second side of the semiconductor layer, and a pad-out structure can be formed. FIGS. 9E-9F illustrate schematic cross-sectional views of an exemplary 3D structure at certain fabricating stages of the operation 830, according to some implementations of the present disclosure.

As shown in FIG. 9E, the undoped portion of the semiconductor layer 910 can be removed from the backside of the second semiconductor structure 970 to expose the lightly doped semiconductor layer 916. The exposed portions of the semiconductor pillars 952 can be doped to form source/drain regions 958 of the GAA transistors 950. In some implementations, second gate structures 948 of the first transistors 940 can be formed on the backside of the lightly doped semiconductor layer 916. The fabricating processes of forming the second gate structures 948 can include forming a gate dielectric layer on the lightly doped semiconductor layer 916 and forming a gate electrode on the gate dielectric layer.

In some implementations, a plurality of second contact structures 994 can be formed on the second side (i.e., backside) of the doped semiconductor layer 916. As shown in FIG. 9E, an insulating layer 960 can be formed to cover the second gate structures 948 of the first transistors 940 and the source/drain regions 958 of the GAA transistors 950. A plurality of openings 962 can be formed in the insulating layer 960 to expose the second gate structures 948, the source/drain regions 958, and/or the all-around gate structures 956. As shown in FIG. 9F, a conductive material can be filled into the openings to form the second contact structures 994. In some implementations, the second contact structures 994 can include source/drain contacts electrically connected to the source/drain regions 958 of the GAA transistors 950, and can further include gate contacts electrically connected to the second gate structures 948 of the first transistors 940 and the all-around gate structures 956 of the GAA transistors 950.

In some implementations as shown in FIG. 9F, a pad-out structure 990 can include a third interconnect layer comprising third interconnect structures 995 embedded in one or more ILD layers and in contact with the second contact structures 994. In some implementations, the third interconnect structures 995 can include any suitable conductive materials including, but not limited to, W, Co, Cu, Al, doped silicon, silicides, or any combination thereof. In some implementations, the pad-out structure 990 can further include conductive pads 999 in contact with the third interconnect structures 995. In some implementations, the one or more ILD layers can include one or more layers of dielectric materials such as silicon oxide, silicon nitride, silicon oxynitride, or any combination thereof, and can be formed by one or more thin film deposition processes, such as ALD, CVD, PVD, any other suitable processes, or any combination thereof. The conductive pads 999 can include conductive materials including, but not limited to, W, Co, Cu, Al, doped silicon, silicides, or any combination thereof.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising an array of memory cells;
a second semiconductor structure including peripheral circuits on the first semiconductor structure, comprising:
a semiconductor layer,
first transistors at a first side of the semiconductor layer close to the first semiconductor structure,
gate all around transistors in the semiconductor layer,
first contact structures on the first side of the semiconductor layer and in contact with the first transistors and the gate all around transistors, and
second contact structures on a second side of the semiconductor layer distant from the first semiconductor structure, and in contact with the gate all around transistors; and
a pad-out structure comprising conductive pads coupled with the second contact structures.

2. The memory device of claim 1, wherein:
the first semiconductor structure further comprises a first interconnect layer comprising first interconnect structures coupled with the array of memory cells; and
the second semiconductor structure further comprises a second interconnect layer comprising second interconnect structures coupled with the first contact structures.

3. The memory device of claim 2, wherein:
the first semiconductor structure is hybrid bonded with the second semiconductor structure in a vertical direction, and
the first interconnect structures are coupled with the second interconnect structures.

4. The memory device of claim 2, wherein the second semiconductor structure further comprises:
isolation structures extending through the semiconductor layer and between the transistors and/or the gate all around transistors.

5. The memory device of claim 1, wherein: the semiconductor layer is a monocrystal silicon layer having a thickness of less than 200 nm.

6. The memory device of claim 1, wherein the pad-out structure further comprises:
a third interconnect layer comprising third interconnect structures coupled between the conductive pads and the second contact structures.

7. The memory device of claim 1, wherein one first transistor comprises:
a first gate on the first side of the semiconductor layer and in contact with one first contact structure; and
a second gate on the second side of the semiconductor layer and in contact with one second contact structure.

8. The memory device of claim 1, wherein:
one of the first contact structures is in contact with a gate of a first gate all around transistor; and
one of the second contact structures is in contact with a gate of a second gate all around transistor.

9. The memory device of claim 1, wherein:
one of the first contact structures is in contact with a first source/drain terminal of one gate all around transistor; and
one of the second contact structures is in contact with a second source/drain terminal of the one gate all around transistor.

10. The memory device of claim 8, wherein:
the one of the first contact structures or the one of the second contact structures is coupled with a through interconnect structure extending through the semiconductor layer.

11. The memory device of claim 1, wherein each gate all around transistor comprises:
a channel in the semiconductor layer;
a first source/drain at the first side of the semiconductor layer;
a second source/drain at the second side of the semiconductor layer;
a gate dielectric layer laterally surrounding the channel, the first source/drain, and the second source/drain; and
a gate structure embedded in the gate dielectric layer and laterally surrounding the channel.

12. The memory device of claim 1, wherein:
a lateral dimension of a first end of each first contact structure close to the semiconductor layer is less than a lateral dimension of a second end of the first contact structure distant from the semiconductor layer; and
a lateral dimension of a first end of each second contact structure close to the semiconductor layer is less than a lateral dimension of a second end of the second contact structure distant from the semiconductor layer.

13. A method of forming a memory device, comprising:
forming a first semiconductor structure comprising an array of memory cells;
forming a second semiconductor structure including peripheral circuits on the first semiconductor structure, comprising:
forming first transistors at a first side of a semiconductor layer,
forming gate all around transistors in the semiconductor layer,
forming first contact structures on the first side of the semiconductor layer and in contact with the gate all around transistors, and
forming second contact structures on a second side of the semiconductor layer distant from the first semiconductor structure, and in contact with the first transistors and the gate all around transistors; and
bonding the first semiconductor structure and the second semiconductor structure.

14. The method of claim 13, wherein:
forming the first semiconductor structure further comprises forming a first interconnect layer comprising first interconnect structures coupled with the array of memory cells; and
forming the second semiconductor structure further comprises forming a second interconnect layer comprising second interconnect structures coupled with the first contact structures.

15. The method of claim 13, wherein forming the second semiconductor structure further comprises:
forming isolation structures extending in the semiconductor layer and between the transistors and/or the gate all around transistors.

16. The method of claim 15, wherein forming the second semiconductor structure further comprises: after forming the first transistors and the gate all around transistors, thinning the semiconductor layer from the second side, such that a thickness of the semiconductor layer is less than 200 nm.

17. The method of claim 13, further comprising:
forming a pad-out structure comprising:
forming a third interconnect layer comprising third interconnect structures in contact with the second contact structures; and
forming conductive pads in contact with the third interconnect structures.

18. The method of claim 16, wherein forming one first transistor comprises: forming a
first gate on the first side of the semiconductor layer; and
after thinning the semiconductor layer, forming a second gate on the second side of the semiconductor layer,
wherein one first contact structure is formed to be in contact with the first gate, and one second contact structure is formed to be in contact with the second gate.

19. The method of claim 18, wherein forming the second semiconductor structure further comprises:
forming a through interconnect structure extending through the semiconductor layer and coupled with the one of the first contact structures or the one of the second contact structures.

20. A memory device, comprising:
a first semiconductor structure comprising an array of memory cells; and
a second semiconductor structure including peripheral circuits on the first semiconductor structure, and comprising:
a semiconductor layer,
a memory control circuit comprising first transistors at a first side of the semiconductor layer close to the first semiconductor structure,
a power supply circuit comprising gate all around transistors in the semiconductor layer,
first contact structures on the first side of the semiconductor layer and in contact with the gate all around transistors, and
second contact structures on a second side of the semiconductor layer distant from the first semiconductor structure, and in contact with the first transistors and the gate all around transistors.
